(19) United States
(12) Patent Application Publication
(10) Pub. No.: US 2024/0363775 A1
(43) Pub. Date: Oct. 31, 2024

(54) Photodetector with Improved Performance

(71) Applicant: Apple Inc., Cupertino, CA (US)

(72) Inventors: Matthew T. Morea, Cupertino, CA (US); Daniel Mahgerefteh, Campbell, CA (US)

(21) Appl. No.: 18/646,270

(22) Filed: Apr. 25, 2024

Related U.S. Application Data
(60) Provisional application No. 63/462,479, filed on Apr. 27, 2023.

(51) Int. Cl. H01L 31/0352; H01L 31/0304; H01L 31/105

(52) U.S. Cl. CPC H01L 31/0352; H01L 31/03046; H01L 31/105

(57) ABSTRACT

A photodetector may include a substrate having a larger lattice constant than an absorber layer. A reverse graded set of buffer layers may provide lattice matching between the substrate and the absorber layer. The substrate may comprise indium arsenide (InAs). The absorber layer may comprise one of indium gallium arsenide (InₓGa₁₋ₓAs), indium arsenide phosphide (InAsₓP₁₋ₓ), and indium aluminum arsenide (InₓAl₁₋ₓAs).

### CROSS-REFERENCE TO RELATED APPLICATION

This application is a nonprovisional and claims the benefit of U.S.C. 35 § 1.119 (e) of U.S. Provisional Patent Application No. 63/462,479, filed Apr. 27, 2023, the contents of which are incorporated herein by reference as if fully described herein.

### TECHNICAL FIELD

Embodiments described herein relate to photodetectors, and in particular to photodetectors having improved performance such as reduced dark current.

### BACKGROUND

Electronic devices such as smartphones and smart watches may include various sensors, which may sense physical phenomena such as movement, environmental conditions, and biometric data about a user. The data from sensors in an electronic device may be used to provide valuable information to a user, such as information about the activity and/or health of the user. Additional sensors in electronic devices may provide more robust information to a user and/or unlock additional applications of the wearable device. Given the wide range of applications for sensors in electronic devices, any new development in the configuration or operation of the sensors therein can be useful. New developments that may be particularly useful are developments that provide additional or improved sensing capability.

### SUMMARY

Embodiments described herein relate to photodetectors, and in particular to photodetectors having improved performance such as reduced dark current. In one embodiment, a photodetector device includes a substrate, a set of buffer layers on the substrate, and an absorber layer on the set of buffer layers. The substrate may comprise indium arsenide (InAs). The set of buffer layers may provide a graded lattice constant that decreases from a bottom surface of the set of buffer layers on the substrate to a top surface of the set of buffer layers opposite the substrate. The absorber layer may be on the top surface of the set of buffer layers. The absorber layer may comprise indium gallium arsenide (InₓGa₁₋ₓAs). The absorber layer may have a lattice constant that is at least 0.4% smaller than a lattice constant of the substrate. The lattice constant of the absorber layer may be matched to the top surface of the set of buffer layers.

In one embodiment, each of the set of buffer layers comprises indium arsenide phosphide (InAsₓP₁₋ₓ).

In one embodiment, each of the set of buffer layers comprises indium aluminum arsenide (InₓAl₁₋ₓAs).

In one embodiment, a cutoff wavelength of the photodetector is at least 1.7 micrometers.

In one embodiment, each buffer layer of the set of buffer layers has a thickness that such that a product of the thickness and a square of a residual strain of the buffer layer relative to a layer on which the buffer layer is provided is less than a predetermined value.

In one embodiment, the set of buffer layers provide a continuously graded lattice constant from the button surface of the set of buffer layers to the top surface of the set of buffer layers.

In one embodiment, the set of buffer layers provide a step-graded lattice constant from the bottom surface of the set of buffer layers to the top surface of the set of buffer layers.

In one embodiment, a photodetector device includes a substrate, a set of buffer layers on the substrate, and an absorber layer on the set of buffer layers. The substrate may comprise indium arsenide (InAs). The set of buffer layers may provide a graded lattice constant that decreases from a bottom surface of the set of buffer layers on the substrate to a top surface of the set of buffer layers opposite the substrate. The absorber layer may be on the top surface of the set of buffer layers. The absorber layer may comprise indium arsenide phosphide (InAsₓP₁₋ₓ). The absorber layer may have a lattice constant that is at least 0.4% smaller than a lattice constant of the substrate. The lattice constant of the absorber layer may be matched to the top surface of the set of buffer layers.

In one embodiment, each of the set of buffer layers comprises indium arsenide phosphide (InAsₓP₁₋ₓ).

In one embodiment, each of the set of buffer layers comprises indium aluminum arsenide (InₓAl₁₋ₓAs).

In one embodiment, a cutoff wavelength of the photodetector is at least 1.7 micrometers.

In one embodiment, each buffer layer of the set of buffer layers has a thickness such that a product of the thickness and a square of a residual strain of the buffer layer relative to a layer on which the buffer layer is provided is less than a predetermined value.

In one embodiment, the set of buffer layers provide a continuously graded lattice constant from the button surface of the set of buffer layers to the top surface of the set of buffer layers.

In one embodiment, the set of buffer layers provide a step-graded lattice constant from the bottom surface of the set of buffer layers to the top surface of the set of buffer layers.

In one embodiment, a photodetector device includes a substrate, a set of buffer layers on the substrate, and an absorber layer on the set of buffer layers. The substrate may comprise indium arsenide (InAs). The set of buffer layers may provide a graded lattice constant that decreases from a bottom surface of the set of buffer layers on the substrate to a top surface of the set of buffer layers opposite the substrate. The absorber layer may be on the top surface of the set of buffer layers. The absorber layer may comprise indium aluminum arsenide (InₓAl₁₋ₓAs). The absorber layer may have a lattice constant that is at least 0.4% smaller than a lattice constant of the substrate. The lattice constant of the absorber layer may be matched to the top surface of the set of buffer layers.

In one embodiment, each of the set of buffer layers comprises indium arsenide phosphide (InAsₓP₁₋ₓ).

In one embodiment, each of the set of buffer layers comprises indium aluminum arsenide (InₓAl₁₋ₓAs).

In one embodiment, a cutoff wavelength of the photodetector is at least 1.7 micrometers.

In one embodiment, each buffer layer of the set of buffer layers has a thickness such that a product of the thickness and a square of a residual strain of the buffer layer relative to a layer on which the buffer layer is provided is less than a predetermined value.

In one embodiment, the set of buffer layers provide a continuously graded lattice constant from the button surface of the set of buffer layers to the top surface of the set of buffer layers.

In one embodiment, the set of buffer layers provide a step-graded lattice constant from the bottom surface of the set of buffer layers to the top surface of the set of buffer layers.

### BRIEF DESCRIPTION OF THE DRAWINGS

Reference will now be made to representative embodiments illustrated in the accompanying figures. It should be understood that the following descriptions are not intended to limit this disclosure to one included embodiment. To the contrary, the disclosure provided herein is intended to cover alternatives, modifications, and equivalents as may be included within the spirit and scope of the described embodiments, and as defined by the appended claims.

FIG. 1 depicts a cross-sectional view of a photodetector, such as described herein.

FIG. 2 depicts a cross-sectional view of a photodetector, such as described herein.

FIG. 3 depicts a cross-sectional view of a photodetector, such as described herein.

FIG. 4 depicts a cross-sectional view of a photodetector, such as described herein.

FIG. 5 is a flowchart depicting example operations of a method of manufacturing a photodetector, such as described herein.

FIGS. 6A and 6B illustrate an electronic device that may include a photodetector, such as described herein.

FIG. 7 illustrates a simplified block diagram of an electronic device that may include a photodetector, such as described herein.

The use of the same or similar reference numerals in different figures indicates similar, related, or identical items.

The use of cross-hatching or shading in the accompanying figures is generally provided to clarify the boundaries between adjacent elements and also to facilitate legibility of the figures. Accordingly, neither the presence nor the absence of cross-hatching or shading conveys or indicates any preference or requirement for particular materials, material properties, element proportions, element dimensions, commonalities of similarly illustrated elements, or any other characteristic, attribute, or property for any element illustrated in the accompanying figures.

Additionally, it should be understood that the proportions and dimensions (either relative or absolute) of the various features and elements (and collections and groupings thereof) and the boundaries, separations, and positional relationships presented therebetween, are provided in the accompanying figures merely to facilitate an understanding of the various embodiments described herein and, accordingly, may not necessarily be presented or illustrated to scale, and are not intended to indicate any preference or requirement for an illustrated embodiment to the exclusion of embodiments described with reference thereto.

### DETAILED DESCRIPTION

Embodiments described herein relate to photodetectors, and in particular to photodetectors having improved performance such as reduced dark current. Photodetectors generate an output signal (e.g., a current) in proportion to electromagnetic radiation (i.e., light) incident to the photodetector. One popular type of photodetector is a PIN diode. PIN diodes include a substrate, one or more buffer layers, and an absorber layer. The materials selected for the substrate, the one or more buffer layers, and the absorber layer determine the performance and characteristics of the photodetector, such as a cutoff wavelength (i.e., long-wavelength cutoff, which is the wavelength above which the photodetector can no longer detect light), dark current (i.e., current through the device when no light is incident thereto), and the like. In particular, a lattice mismatch between the substrate and the absorber layer may determine a strain and dislocation density in the absorber layer, which may in turn determine a dark current for the photodetector.

Conventional photodetectors for detecting SWIR light have used an indium phosphide (InP) substrate with an indium gallium arsenide (InₓGa₁₋ₓAs) absorber layer. Indium gallium arsenide (InₓGa₁₋ₓAs) may have a lattice constant larger than that of indium phosphide (InP), and in some cases significantly larger (the lattice constant of indium gallium arsenide (InₓGa₁₋ₓAs) is inversely proportional to the concentration of gallium therein). The one or more buffer layers of a conventional photodetector attempt to match the lattice constant of indium phosphide (InP) to the lattice constant of indium gallium arsenide (InₓGa₁₋ₓAs) by transitioning between the two. This means that the one or more buffer layers transition from a smaller lattice constant to a larger lattice constant between the substrate and the absorber layer. This results in a compressive strain on the buffer layers and absorber layer. The compressive strain, along with the magnitude of the lattice mismatch between the substrate and the absorber layer, may result in significant dislocation density in the absorber layer. This may in turn result in a relatively large dark current for the photodetector. The lattice constant of the absorber layer is proportional to the cutoff wavelength of the photodetector. Accordingly, efforts to reduce the lattice mismatch between the substrate and the absorber layer by decreasing the lattice constant of the absorber layer results in a proportional decrease in cutoff wavelength. This may result in photodetectors not suited for detecting SWIR light.

The photodetectors discussed herein utilize a substrate having a larger lattice constant than an absorber layer, and a set of buffer layers that provide a lattice constant that decreases along a thickness of the set of buffer layers from the substrate to the absorber layer. A buffer layer or set of buffer layers having a lattice constant that decreases along a thickness thereof from a substrate to an absorber layer is referred to herein as “reverse graded.” In particular, photodetectors discussed herein use an indium arsenide (InAs) substrate, and may use either an indium gallium arsenide (InₓGa₁₋ₓAs), indium arsenide phosphide (InAsₓP₁₋ₓ), or indium aluminum arsenide (InₓAl₁₋ₓAs) absorber layer. The lattice mismatch between indium arsenide (InAs) and any of indium gallium arsenide (InₓGa₁₋ₓAs), indium arsenide phosphide (InAsₓP₁₋ₓ), or indium aluminum arsenide (InₓAl₁₋ₓAs) may, depending on the desired cutoff wavelength, be significantly less than that in conventional photodiodes using an indium phosphide (InP) substrate. Further, the lattice mismatch is in the opposite direction compared to conventional photodiodes. That is, the lattice constant of the substrate is larger than the lattice constant of the absorber layer. This allows the set of buffer layers to be reverse graded, trading compressive strain for tensile strain, which may be easier to design around in some cases. The combination of reduced lattice mismatch and reverse graded buffer layer(s) may result in reduced dislocation density in the absorber layer and thus lower dark current compared to conventional photodiodes. Overall, such a configuration may provide a photodetector having improved performance in various aspects, such as, for example, higher cutoff wavelength and lower dark current.

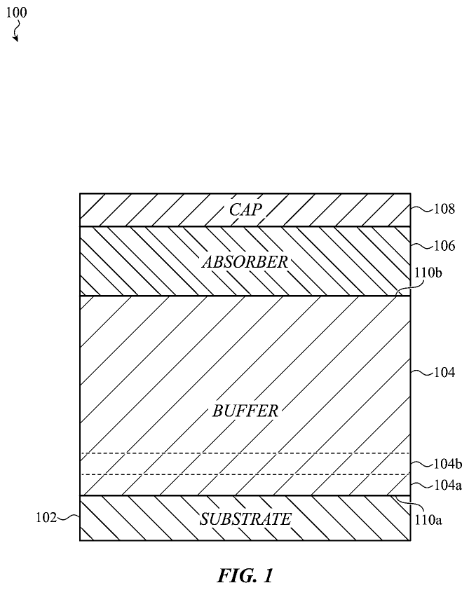

These foregoing and other embodiments are discussed below with reference to FIGS. 1-7. However, those skilled in the art will readily appreciate that the detailed description given herein with respect to these figures is for explanation only and should not be construed as limiting.

FIG. 1 shows a cross-sectional view of a photodetector 100 according to one embodiment of the present disclosure. The photodetector 100 includes a substrate 102, a set of buffer layers 104 on the substrate 102, an absorber layer 106 on the set of buffer layers 104, and a cap layer 108 on the absorber layer 106. The material system of the substrate 102 and the absorber layer 106 may be chosen such that a lattice constant of the absorber layer 106 is smaller than a lattice constant of the substrate 102. In particular, the material system of the substrate 102 and the absorber layer 106 may be chosen such that the lattice constant of the absorber layer 106 is at least 0.4% smaller than the lattice constant of the substrate 102. In various embodiments, the lattice constant of the absorber layer 106 is at least 0.5% smaller, at least 0.6% smaller, at least 0.7% smaller, at least 0.8% smaller, at least 0.9% smaller, or at least 1.0% smaller than the lattice constant of the substrate 102. The set of buffer layers 104, which may include one or more buffer layers 104, is reverse graded, such that the set of buffer layers 104 transitions from a larger lattice constant at or near the lattice constant of the substrate 102 at a bottom surface 110a thereof to a smaller lattice constant at or near the lattice constant of the absorber layer 106 at a top surface 110b thereof. The set of buffer layers 104 may transition in lattice constant in a continuous or step-wise manner along a thickness thereof, and may be provided as a single layer or multiple layers. In some embodiments, a lattice constant of the set of buffer layers 104 at the top surface 110b is matched to the lattice constant of the absorber layer 106. A lattice constant of the set of buffer layers 104 at the bottom surface 110a may similarly be matched to the lattice constant of the substrate 102.

In particular, in one embodiment the substrate 102 comprises indium arsenide (InAs) and the absorber layer 106 comprises indium gallium arsenide (InₓGa₁₋ₓAs). In particular, the absorber layer 106 may comprise extended indium gallium arsenide (InₓGa₁₋ₓAs), which as discussed herein is any composition of indium gallium arsenide (InₓGa₁₋ₓAs) having a cutoff wavelength greater than 1.7 μm. In some embodiments, the absorber layer 106 may be configured (i.e., the relative concentrations of indium and gallium chosen) to provide a cutoff wavelength of at least 2.0 μm, and up to 2.7 μm. In the present embodiment, each of the set of buffer layers 104 may comprise indium arsenide phosphide (InAsₓP₁₋ₓ). In particular, the set of buffer layers 104 may comprise layers of indium arsenide phosphide (InAsₓP₁₋ₓ) wherein an arsenic concentration of each layer decreases from the bottom surface 110a to the top surface 110b (such that there is a corresponding increase in phosphorous concentration) to provide a step-wise transition in lattice constant from the bottom surface 110a to the top surface 110b, or a single layer in which the arsenic concentration continuously decreases from the bottom surface 110a to the top surface 110b in a linear or otherwise continuous manner to provide a continuous transition in lattice constant from the bottom surface 110a to the top surface 110b. Accordingly, a lattice constant of the set of buffer layers 104 may transition from a lattice constant at or near the lattice constant of the substrate 102 to a lattice constant at or near the lattice constant of the absorber layer 106. The cap layer 108 may comprise one of indium arsenide phosphide (InAsₓP₁₋ₓ), indium aluminum arsenide (InₓAl₁₋ₓAs), or an antimony containing group III-V alloy.

In another embodiment wherein the substrate 102 comprises indium arsenide (InAs) and the absorber layer 106 comprises indium gallium arsenide (InₓGa₁₋ₓAs), each of the set of buffer layers 104 may comprise indium aluminum arsenide (InₓAl₁₋ₓAs). In particular, the set of buffer layers 104 may comprise layers of indium aluminum arsenide (InₓAl₁₋ₓAs) wherein an aluminum concentration of each layer increases from the bottom surface 110a to the top surface 110b (such that there is a corresponding decrease in indium concentration) to provide a step-wise transition in lattice constant from the bottom surface 110a to the top surface 110b, or a single layer in which the aluminum concentration increases from the bottom surface 110a to the top surface 110b in a linear or otherwise continuous manner to provide a continuous transition in lattice constant from the bottom surface 110a to the top surface 110b. Accordingly, a lattice constant of the set of buffer layers 104 may transition from a lattice constant at or near the lattice constant of the substrate 102 to a lattice constant at or near the lattice constant of the absorber layer 106. The cap layer 108 may comprise one of indium arsenide phosphide (InAsₓP₁₋ₓ), indium aluminum arsenide (InₓAl₁₋ₓAs), or an antimony containing group III-V alloy.

In one embodiment the substrate 102 comprises indium arsenide (InAs) and the absorber layer 106 comprises indium arsenide phosphide (InAsₓP₁₋ₓ). In particular, the absorber layer 106 may be configured (i.e., the relative concentrations of arsenic and phosphorous chosen) to provide a cutoff wavelength of at least 2.0 μm, and up to 2.7 μm. In the present embodiment, each of the set of buffer layers 104 may comprise indium arsenide phosphide (InAsₓP₁₋ₓ). In particular, the set of buffer layers 104 may comprise layers of indium arsenide phosphide (InAsₓP₁₋ₓ) wherein an arsenic concentration of each layer decreases from the bottom surface 110a to the top surface 110b (such that there is a corresponding increase in phosphorous concentration) to provide a step-wise transition in lattice constant from the bottom surface 110a to the top surface 110b, or a single layer in which the arsenic concentration continuously decreases from the bottom surface 110a to the top surface 110b in a linear or otherwise continuous manner to provide a continuous transition in lattice constant from the bottom surface 110a to the top surface 110b. Accordingly, a lattice constant of the set of buffer layers 104 may transition from a lattice constant at or near the lattice constant of the substrate 102 to a lattice constant at or near the lattice constant of the absorber layer 106. The cap layer 108 may comprise one of indium arsenide phosphide (InAsₓP₁₋ₓ), indium aluminum arsenide (InₓAl₁₋ₓAs), or an antimony containing group III-V alloy.

In another embodiment wherein the substrate 102 comprises indium arsenide (InAs) and the absorber layer 106 comprises indium arsenide phosphide (InAsₓP₁₋ₓ), each of the set of buffer layers 104 may comprise indium aluminum arsenide (InₓAl₁₋ₓAs). In particular, the set of buffer layers 104 may comprise layers of indium aluminum arsenide (InₓAl₁₋ₓAs) wherein an aluminum concentration of each layer increases from the bottom surface 110a to the top surface 110b (such that there is a corresponding decrease in indium concentration) to provide a step-wise transition in lattice constant from the bottom surface 110a to the top surface 110b, or a single layer in which the aluminum concentration increases from the bottom surface 110a to the top surface 110b in a linear or otherwise continuous manner to provide a continuous transition in lattice constant from the bottom surface 110a to the top surface 110b. Accordingly, a lattice constant of the set of buffer layers 104 may transition from a lattice constant at or near the lattice constant of the substrate 102 to a lattice constant at or near the lattice constant of the absorber layer 106. The cap layer 108 may comprise one of indium arsenide phosphide (InAsₓP₁₋ₓ), indium aluminum arsenide (InₓAl₁₋ₓAs), or an antimony containing group III-V alloy.

In one embodiment the substrate 102 comprises indium arsenide (InAs) and the absorber layer 106 comprises indium aluminum arsenide (InₓAl₁₋ₓAs). In particular, the absorber layer 106 may be configured (i.e., the relative concentrations of indium and aluminum chosen) to provide a cutoff wavelength of at least 2.0 μm, and up to 2.7 μm. In the present embodiment, each of the set of buffer layers 104 may comprise indium arsenide phosphide (InAsₓP₁₋ₓ). In particular, the set of buffer layers 104 may comprise layers of indium arsenide phosphide (InAsₓP₁₋ₓ) wherein an arsenic concentration of each layer decreases from the bottom surface 110a to the top surface 110b (such that there is a corresponding increase in phosphorous concentration) to provide a step-wise transition in lattice constant from the bottom surface 110a to the top surface 110b, or a single layer in which the arsenic concentration continuously decreases from the bottom surface 110a to the top surface 110b in a linear or otherwise continuous manner to provide a continuous transition in lattice constant from the bottom surface 110a to the top surface 110b. Accordingly, a lattice constant of the set of buffer layers 104 may transition from a lattice constant at or near the lattice constant of the substrate 102 to a lattice constant at or near the lattice constant of the absorber layer 106. The cap layer 108 may comprise one of indium arsenide phosphide (InAsₓP₁₋ₓ), indium aluminum arsenide (InₓAl₁₋ₓAs), or an antimony containing group III-V alloy.

In another embodiment wherein the substrate 102 comprises indium arsenide (InAs) and the absorber layer 106 comprises indium aluminum arsenide (InₓAl₁₋ₓAs), each of the set of buffer layers 104 may comprise indium aluminum arsenide (InₓAl₁₋ₓAs). In particular, the set of buffer layers 104 may comprise layers of indium aluminum arsenide (InₓAl₁₋ₓAs) wherein an aluminum concentration of each layer increases from the bottom surface 110a to the top surface 110b (such that there is a corresponding decrease in indium concentration) to provide a step-wise transition in lattice constant from the bottom surface 110a to the top surface 110b, or a single layer in which the aluminum concentration increases from the bottom surface 110a to the top surface 110b in a linear or otherwise continuous manner to provide a continuous transition in lattice constant from the bottom surface 110a to the top surface 110b. Accordingly, a lattice constant of the set of buffer layers 104 may transition from a lattice constant at or near the lattice constant of the substrate 102 to a lattice constant at or near the lattice constant of the absorber layer 106. The cap layer 108 may comprise one of indium arsenide phosphide (InAsₓP₁₋ₓ), indium aluminum arsenide (InₓAl₁₋ₓAs), or an antimony containing group III-V alloy.

Using an indium arsenide (InAs) substrate 102 along with any of the materials for the absorber layer 106 discussed above, or, generally, any other semiconductor materials having a smaller lattice constant and desired cutoff wavelength allows for a smaller lattice mismatch between the substrate 102 and the absorber layer 106. Further, the directionality of the lattice mismatch (larger to smaller, from the substrate 102 to the absorber layer 106) allows for the use of a reverse graded set of buffer layers 104, which, as discussed above, may allow for reduced cracks, deformations, and/or dislocations, which may reduce dark current. For example, the lattice mismatch between indium phosphide (InP) and extended indium gallium arsenide (InₓGa₁₋ₓAs) is about 1.8% for a cutoff wavelength of 2.5 μm, while a lattice mismatch between indium arsenide (InAs) and extended indium gallium arsenide (InₓGa₁₋ₓAs) is about 1.3% for the same cutoff wavelength. The reduced lattice mismatch may allow for improved cutoff frequency in some embodiments, since there may be more design flexibility in the bandgap of the absorber layer 106 while providing desired performance in other aspects such as dark current. The various embodiments for the photodetector 100 described above may provide a cutoff wavelength between 2.0 μm and 2.7 μm. Generally, however, the principles of the present disclosure may provide a photodetector 100 having a cutoff wavelength greater than 1.7 μm, greater than 1.8 μm, greater than 1.9 μm, greater than 2.0 μm, greater than 2.1 μm, greater than 2.2 μm, greater than 2.3 μm, greater than 2.4 μm, and greater than 2.5 μm, depending on the composition of the absorber layer 106 and other factors.

As discussed above, an important factor in the performance of the photodetector 100 is strain, and in particular strain in the absorber layer 106, as well as dislocation density, which may be related to strain. Both strain and dislocation density may be proportional to dark current in the photodetector 100. Accordingly, any reductions in strain and/or dislocation density may result in improved performance of the photodetector 100. Generally, using the indium arsenide (InAs) substrate 102 along with the absorber layer 106 materials described herein provides a smaller lattice mismatch between the substrate 102 and the absorber layer 106, resulting in lower strain overall. In some embodiments, to further reduce strain and/or dislocation density, a thickness of each buffer layer 104 may be selected based on a square of a residual strain of the buffer layer 104 relative to a layer on which the buffer layer 104 is provided. Specifically, the thickness of a given buffer layer may be selected such that a product of the thickness and the square of the residual strain of the buffer layer is less than a predetermined value. The predetermined value may represent a value above which cracking will occur in a buffer layer, and thus designing each of the buffer layers to meet this criteria (i.e., the product of thickness and the square of the residual strain being less than the predetermined value) may reduce crack formation and/or dislocation density, which may in turn reduce dark current associated with the photodetector 100.

In some instances, each of the buffer layers 104 is configured to have a product of thickness and the square of the residual strain that has a common value. In some embodiments, the thickness of each buffer layer 104 (e.g., a first buffer layer 104a, a second buffer layer 104b, and so on) may be defined by Equation 1:

$${t}_{c} = \frac{{t}_{pd}}{{∈}^{2}} . \qquad Equation 1$$

where t_{c} is the thickness of the buffer layer 104, t_{pd} is a predefined thickness, and ∈ is the residual strain of the buffer layer 104 relative to the layer on which the buffer layer 104 is provided. In some embodiments, the predefined thickness t_{pd} may be between 10 picometers and 15 picometers. In particular, the predefined thickness t_{pd} may be 13 picometers.

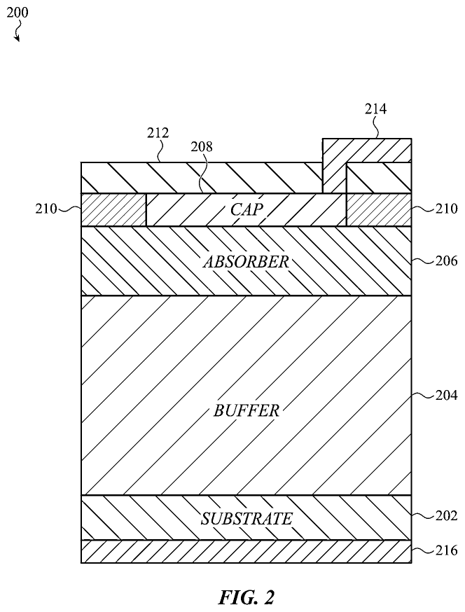

The substrate 102, the set of buffer layers 104, and the absorber layer 106 may have a first conductivity type. The cap layer 108 may have a second conductivity type opposite the first conductivity type. For example, the substrate 102, the set of buffer layers 104, and the absorber layer 106 may be n-type, while the cap layer 108 is p-type. In some embodiments, the cap layer 108 may be provided having the first conductivity type and subsequently have one or more regions of the second conductivity type provided therein (e.g., via diffusion doping). In other embodiments, the cap layer 108 may be provided having the second conductivity type and subsequently have one or more regions of the first conductivity type provided therein. The substrate 102, the set of buffer layers 104, the absorber layer 106, and the cap layer 108 may be doped to provide a PIN structure suitable for forming a PIN diode as discussed below with respect to FIGS. 2-4. In some embodiments, the cap layer 108 may have a larger bandgap than the absorber layer 106 to assist in absorption of light having a desired wavelength.

FIG. 2 shows a cross-sectional view of an exemplary planar photodetector 200 according to one embodiment of the present disclosure. The planar photodetector 200 includes a substrate 202, a set of buffer layers 204, an absorber layer 206, and a cap layer 208, which may correspond with the substrate 102, the set of buffer layers 104, the absorber layer 106, and the cap layer 108 in FIG. 1. In addition, the planar photodetector 200 may include one or more dark current reduction regions 210 along a sidewall thereof in the cap layer 208. The dark current reduction regions 210 may have an opposite conductivity type to the cap layer 208 (e.g., if the cap layer 208 is a p-type layer, the dark current reduction regions 210 may be n-type, and vice-versa). In various embodiments, either the dark current reduction regions 210 or the portion of the cap layer 208 outside of the dark current reduction regions 210 may be provided by a subsequent processing step after providing the cap layer 208 such as diffusion. The dark current reduction regions 210 may prevent current from flowing in the area in which they are provided in the cap layer 208, and in the area below them in the absorber layer 206, effectively reducing a width of a PN junction between the cap layer 208 and the absorber layer 206. Since dislocations tend to be concentrated towards the sidewalls, the dark current reduction regions 210 may prevent current flow in areas having high dislocation density, which may reduce dark current within the planar photodetector 200. The planar photodetector 200 may further include an anti-reflective coating 212, a first contact 214 in electrical contact with the cap layer 208, and a second contact 216 in electrical contact with the substrate 202.

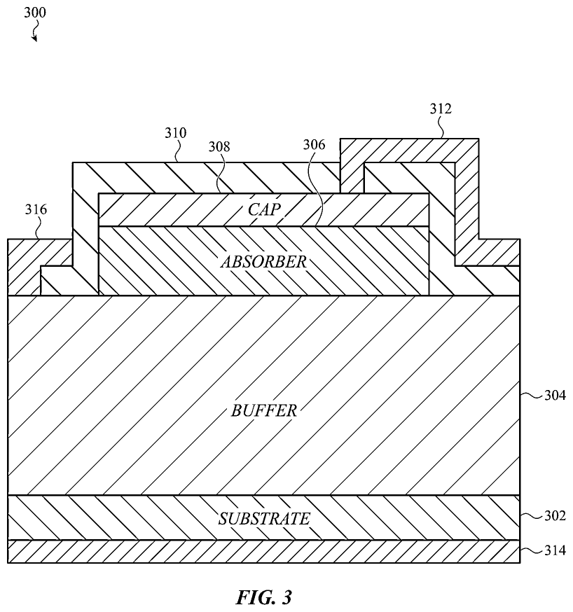

FIG. 3 shows a cross-sectional view of an exemplary mesa photodetector 300 according to one embodiment of the present disclosure. The mesa photodetector 300 includes a substrate 302, a set of buffer layers 304, an absorber layer 306, and a cap layer 308, which may correspond with the substrate 102, the set of buffer layers 104, the absorber layer 106, and the cap layer 108 in FIG. 1. Notably, the absorber layer 306 and the cap layer 308 form a mesa on the set of buffer layers 304. In addition, the mesa photodetector 300 includes an anti-reflective coating 310, a first contact 312 in electrical contact with the cap layer 308, a second contact 314 in electrical contact with the substrate 302, and a third contact 316 in electrical contact with the set of buffer layers 304.

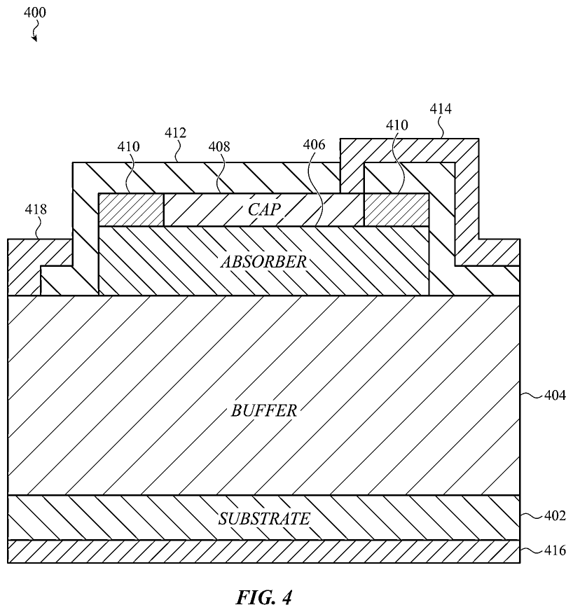

FIG. 4 shows a cross-sectional view of an exemplary hybrid photodetector 400. The hybrid photodetector 400 includes a substrate 402, a set of buffer layers 404, an absorber layer 406, and a cap layer 408, which may correspond with the substrate 102, the set of buffer layers 104, the absorber layer 106, and the cap layer 108 in FIG. 1. Notably, the absorber layer 406 and the cap layer 408 form a mesa on the set of buffer layers 404. In addition, the hybrid photodetector 400 includes one or more dark current reduction regions 410 along a sidewall of the mesa in the cap layer 408. The dark current reduction regions 410 may have an opposite conductivity type to the cap layer 408 (e.g., if the cap layer 408 is a p-type layer, the dark current reduction regions 410 may be n-type, and vice-versa). In various embodiments, either the dark current reduction regions 410 or the portion of the cap layer 408 outside of the dark current reduction regions 410 may be provided by a subsequent processing step after providing the cap layer 408 such as a diffusion doping step. The hybrid photodetector 400 may further include an anti-reflective coating 412, a first contact 414 in electrical contact with the cap layer 408, a second contact 416 in electrical contact with the substrate 402, and a third contact 418 in electrical contact with the set of buffer layers 404.

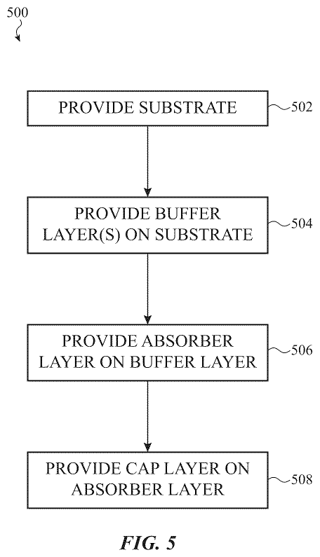

FIG. 5 is a flow diagram illustrating a method 500 for manufacturing a photodetector according to one embodiment of the present disclosure. At operation 502, the substrate is provided. The substrate may be grown as a crystal ingot, sliced, and polished or otherwise processed as necessary to provide a wafer. At operation 504, a set of buffer layers are provided on the substrate. The buffer layers may be deposited by any suitable process, such as a metal organic chemical vapor deposition (MOCVD) process, a molecular beam epitaxy (MBE) process, or the like. The set of buffer layers may be provided as a single layer (i.e., deposited in a single step) or provided as multiple discrete layers. The set of buffer layers may provide a continuous transition in lattice constant along a thickness thereof, or a step-wise transition in lattice constant along multiple discrete buffer layers, each having a different lattice constant. At operation 506, an absorber layer is provided on the buffer layer. The absorber layer may be provided in any suitable manner, such as via a MOCVD or MBE process. As discussed above, the absorber layer may have a smaller lattice constant than the substrate. Specifically, the lattice constant of the absorber layer may be at least 0.4% less than the lattice constant of the substrate. The set of buffer layers may transition between the lattice constant of the substrate (or a lattice constant near that of the substrate) to the lattice constant of the absorber layer (or a lattice constant near that of the absorber layer). Accordingly, the set of buffer layers may be reverse graded. The substrate, the set of buffer layers, and the absorber layer may comprise any of the combinations of material systems discussed above with respect to FIG. 1.

At operation 508, a cap layer is provided on the absorber layer. The cap layer may be provided in any suitable manner, such as via a MOCVD or MBE process. The cap layer may provide one or more regions having an opposite conductivity type to the absorber layer, the set of buffer layers, and the substrate to provide a PIN structure as discussed above. In doing so, the cap layer may be provided having one conductivity type and subsequently one or more regions having a different conductivity type may be provided therein (e.g., via diffusion doping). One or more additional layers or features may further be provided, such as an anti-reflective coating and one or more contacts as discussed above with respect to FIGS. 2-4. The one or more features may also include a mesa structure provided by the absorber layer and the cap layer as discussed above with respect to FIGS. 3-4.

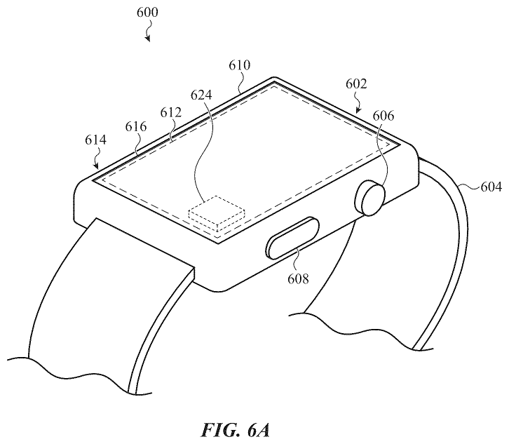

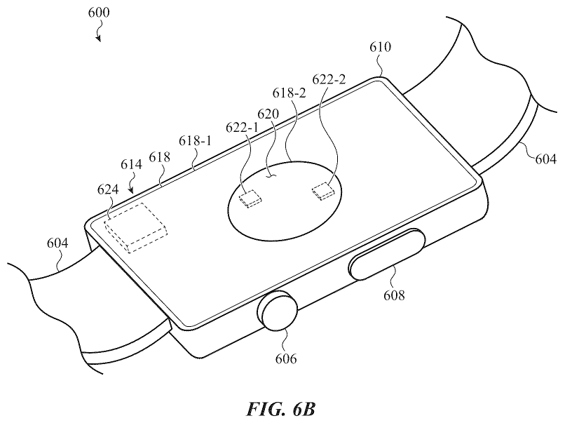

FIGS. 6A and 6B show an example of a wearable device 600 that may incorporate one or more sensors, including one or more photodetectors as discussed herein. Specifically, FIG. 6A shows a front isometric view of the wearable device 600, while FIG. 6B shows a back isometric view of the wearable device 600. The sensors of the wearable device 600 may be used, for example, to acquire biometric data from a user (e.g., heart rate, respiration rate, blood pressure, blood flow rate, blood oxygenation), determine touch or gesture input from a user, or to determine a status of the wearable device 600 (e.g., whether the wearable device is being worn, one or more ambient environmental conditions). While the wearable device 600 is shown having the form factor of a watch, the wearable device 600 could by any suitable type of wearable device having any form factor. Further, the principles of the present disclosure apply equally to non-wearable devices such as smartphones, tablets, laptop computers, desktop computers, and the like.

The wearable device 600 includes a body 602 (e.g., a watch body) and a band 604. The body 602 may include an input or selection device, such as a crown 606 or a button 608. The band 604 may be attached to a housing 610 of the body 602, and may be used to attach the body 602 to a body part of a user (e.g., an arm, wrist, leg, ankle, or waist). The housing 610 may at least partially surround a display 612. In some embodiments, the housing 610 may include a sidewall 614, which may support a front cover 616 (shown in FIG. 6A) and/or a back cover 618 (shown in FIG. 6B). The front cover 616 may be positioned over the display 612, and may provide a window through which the display 612 is viewed. In some embodiments, the display 612 may be attached to (or about) the sidewall 614 and/or the front cover 616. In other embodiments, the display 612 may not be included and/or the housing 610 may have an alternative configuration.

The display 612 may include one or more light emitting elements including, for example, light-emitting elements that define a light-emitting diode (LED) display, an organic LED (OLED) display, a liquid crystal display (LCD), an electroluminescent (EL) display, or any other type of display. In some embodiments, the display 612 may include, or be associated with, one or more touch and/or force sensors that are configured to detect touch and/or force applied to the front cover 616.

In some embodiments, the sidewall 614 of the housing 610 may be formed using one or more metals (e.g., aluminum or stainless steel), polymers (e.g., plastics), ceramics, or composites (e.g., carbon fiber). The front cover 616 may be formed, for example, using one or more of glass, a crystal (e.g., sapphire), or a transparent polymer (e.g., plastic) that enables a user to view the display 612 through the front cover 616. In some cases, a portion of the front cover 616 (e.g., a perimeter portion of the front cover 616) may be coated in an opaque ink to obscure components included within the housing 610. In some cases, all of the exterior components may be formed of a transparent material, and the components of the wearable device 600 may or may not be obscured by an opaque ink or opaque structure within the housing 610.

The back cover 618 may be formed using the same material or materials used to form the sidewall 614 and/or the front cover 616. In some cases, the back cover 618 may be part of a monolithic element that also forms the sidewall 614. In other cases, and as shown, the back cover 618 may be a multi-part back cover, such as a back cover having a first back cover portion 618-1 attached to the sidewall 614 and a second back cover portion 618-2 attached to the first back cover portion 618-1. The second back cover portion 618-2 may in some embodiments have a circular perimeter and an arcuate exterior surface 620 (i.e., an exterior surface 620 having an arcuate profile).

The front cover 616, the back cover 618, and the first back cover portion 618-1 may be mounted to the sidewall 614 using fasteners, adhesives, seals, gaskets, or other components. The second back cover portion 618-2, when present, may be mounted to the first back cover portion 618-1 using fasteners, adhesives, seals, gaskets, or other components.

A display stack or device stack (hereinafter referred to as a “stack”) including the display 612 may be attached (or abutted) to an interior surface of the front cover 616 and extend into an interior volume of the wearable device 600. In some cases, the stack may include a touch sensor (e.g., a grid of capacitive, resistive, strain based, ultrasonic, or other type of touch sensing elements), or other layers of optical, mechanical, electrical, or other types of components. In some cases, the touch sensor (or part of a touch sensor system) may be configured to detect a touch applied to an outer surface of the front cover 616 (e.g., to a display surface of the wearable device 600).

The wearable device 600 may include various sensors 622. For purposes of illustration, the wearable device 600 is shown having a first sensor 622-1 and a second sensor 622-2. The first sensor 622-1 may be a photodetector as discussed herein. The second sensor 622-2 may be a different type of sensor such as a temperature sensor, which may be used to sense the same or different data as the first sensor 622-1. The wearable device 600 may include circuitry 624 (e.g., processing circuitry and/or other components) configured to determine or extract, at least partly in response to signals received directly or indirectly from sensors therein (e.g., the first sensor 622-1 and the second sensor 622-2), data about the user (e.g., biometric data), touch or gesture input from a user, a status of the wearable device 600, and/or data about the environment surrounding the wearable device 600. In doing so, the circuitry 624 may process signals from sensors therein using any suitable transformations, approximations, mathematical operations, and/or machine learning models. In some embodiments, the circuitry 624 may be configured to convey the determined or extracted parameters or statuses to a user of the wearable device 600. For example, the circuitry 624 may cause the indication or indications to be displayed on the display 612, indicated via audio or haptic outputs, transmitted via a wireless communications interface or other communications interface, and so on. The circuitry 624 may also or alternatively maintain or alter one or more settings, functions, or embodiments of the wearable device 600, including, in some cases, what is displayed on the display 612.

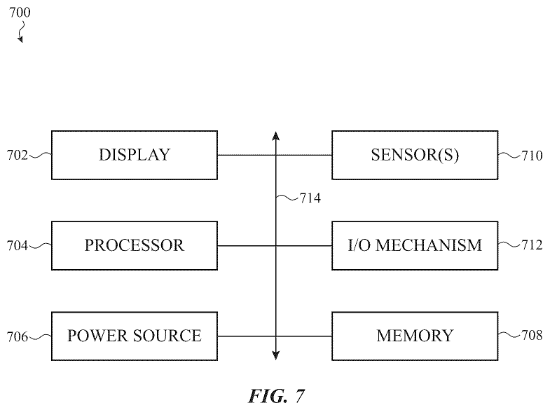

To illustrate a more general functional device that may include one or more electromagnetic radiation sensors as discussed herein, FIG. 7 shows a sample electrical block diagram of a device 700. The device 700 may include a display 702 (e.g., a light-emitting display), a processor 704, (also referred to herein as processing circuitry), a power source 706, a memory 708, or storage device, a sensor system 710, and an input/output (I/O) mechanism 712 (e.g., an I/O device, an I/O port, or a haptic I/O interface). The processor 704 may communicate, either directly or indirectly, with some or all of the other components of the device 700. For example, a system bus or other communication mechanism 714 can provide communication between the display 702, the processor 704, the power source 706, the memory 708, the sensor system 710, and the I/O mechanism 712.

The processor 704 may be implemented as any electronic device capable of processing, receiving, or transmitting data or instructions, whether such data or instructions is in the form of software or firmware or otherwise encoded. For example, the processor 704 may include a microprocessor, a central processing unit (CPU), an application-specific integrated circuit (ASIC), a digital signal processor (DSP), a controller, or a combination of such devices. As described herein, the term “processor” or “processing circuitry” is meant to encompass a single processing unit, multiple processors, multiple processing units, or other suitably configured computing element or elements.

It should be noted that the components of the device 700 can be controlled by multiple processors. For example, select components of the device 700 (e.g., the sensor system 710) may be controlled by a first processor and other components of the wearable device (e.g., the display 702) may be controlled by a second processor, where the first and second processors may or may not be in communication with each other.

The power source 706 can be implemented with any device capable of providing energy to the device 700. For example, the power source 706 may include one or more batteries or rechargeable batteries. Additionally or alternatively, the power source 706 may include a power connector or power cord that connects the device 700 to another power source, such as a wall outlet.

The memory 708 may store electronic data that can be used by the device 700. For example, the memory 708 may store electrical data or content such as, for example, audio and video files, documents and applications, device settings and user preferences, timing signals, control signals, and data structures and databases. The memory 708 may include any type of memory. By way of example only, the memory 708 may include random access memory (RAM), read-only memory (ROM), flash memory, removeable memory, other types of storage elements, or combinations of such memory types.

The device 700 may also include one or more sensor systems 710 positioned almost anywhere thereon. For example, the sensor system may include one or more photodetectors as discussed herein. The sensor system 710 may be configured to sense one or more types of parameters, such as but not limited to: vibration, light, touch, force, heat, movement, relative motion, biometric data (e.g., biological parameters) of a user, air quality, proximity, position, or connectedness. By way of example, the sensor system 710 may include one or more photodetectors, a heat sensor, a position sensor, a light or optical sensor, an accelerometer, a pressure transducer, a gyroscope, a magnetometer, a health monitoring sensor, and/or an air quality sensor. Additionally, the one or more sensor system 710 may utilize any suitable sensing technology including, but not limited to, interferometric, magnetic, capacitive, ultrasonic, resistive, optical, acoustic, piezoelectric, or thermal technologies.

The I/O mechanism 712 may transmit or receive data from a user or another electronic device. The I/O mechanism 712 may include the display 702, a touch sensing input surface, a crown, one or more buttons (e.g., a graphical user interface “home” button), one or more cameras (including an under-display camera), one or more microphones or speakers, one or more ports such as a microphone port, and/or a keyboard. Additionally or alternatively, the I/O mechanism 712 may transmit electronic signals via a communications interface, such as a wireless, wired, and/or optical communications interface. Examples of wireless and wired communications interfaces include, but are not limited to, cellular and Wi-Fi communications interfaces.

These foregoing embodiments depicted in FIGS. 1-7 and the various alternatives thereof and variations thereto are presented, generally, for purposes of explanation, and to facilitate an understanding of various configurations and constructions of a system, such as described herein. However, it will be apparent to one skilled in the art that some of the specific details presented herein may not be required in order to practice a particular described embodiment, or an equivalent thereof.

Thus, it is understood that the foregoing and following descriptions of specific embodiments are presented for the limited purposes of illustration and description. These descriptions are not targeted to be exhaustive or to limit the disclosure to the precise forms recited herein. To the contrary, it will be apparent to one of ordinary skill in the art that many modifications and variations are possible in view of the above teachings.

As used herein, the phrase “at least one of” preceding a series of items, with the term “and” or “or” to separate any of the items, modifies the list as a whole, rather than each member of the list. The phrase “at least one of” does not require selection of at least one of each item listed; rather, the phrase allows a meaning that includes at a minimum one of the items, and/or at a minimum one of any combination of the items, and/or at a minimum one of each of the items. By way of example, the phrases “at least one of A, B, and C” or “at least one of A, B, or C” each refer to only A, only B, or only C; any combination of A, B, and C; and/or one or more of each of A, B, and C. Similarly, it may be appreciated that an order of elements presented for a conjunctive or disjunctive list provided herein should not be construed as limiting the disclosure to only that order provided.

One may appreciate that although many embodiments are disclosed above, that the operations and steps presented with respect to methods and techniques described herein are meant as exemplary and accordingly are not exhaustive. One may further appreciate that alternate step order or fewer or additional operations may be required or desired for particular embodiments.

Although the disclosure above is described in terms of various exemplary embodiments and implementations, it should be understood that the various features, aspects and functionality described in one or more of the individual embodiments are not limited in their applicability to the particular embodiment with which they are described, but instead can be applied, alone or in various combinations, to one or more of the some embodiments of the invention, whether or not such embodiments are described and whether or not such features are presented as being a part of a described embodiment. Thus, the breadth and scope of the present invention should not be limited by any of the above-described exemplary embodiments but is instead defined by the claims herein presented.

What is claimed is:

1. A photodetector device, comprising:
a substrate comprising indium arsenide (InAs);
a set of buffer layers on the substrate, the set of buffer layers providing a graded lattice constant that decreases from a bottom surface of the set of buffer layers on the substrate to a top surface of the set of buffer layers opposite the substrate; and
an absorber layer on the top surface of the set of buffer layers, the absorber layer comprising indium gallium arsenide (InₓGa₁₋ₓAs) and having a lattice constant that is at least 0.4% smaller than a lattice constant of the substrate, the lattice constant of the absorber layer being matched to the top surface of the set of buffer layers.

2. The photodetector of claim 1, wherein each of the set of buffer layers comprises indium arsenide phosphide (InAsₓP₁₋ₓ).

3. The photodetector of claim 1, wherein each of the set of buffer layers comprises indium aluminum arsenide (InₓAl₁₋ₓAs).

4. The photodetector of claim 1, wherein a cutoff wavelength of the photodetector is at least 1.7 micrometers.

5. The photodetector of claim 1, wherein each buffer layer of the set of buffer layers has a thickness such that a product of the thickness and a square of a residual strain of the buffer layer relative to a layer on which the buffer layer is provided is less than a predetermined value.

6. The photodetector of claim 1, wherein the set of buffer layers provide a continuously graded lattice constant from the bottom surface of the set of buffer layers to the top surface of the set of buffer layers.

7. The photodetector of claim 1, wherein the set of buffer layers provide a step-graded lattice constant from the bottom surface of the set of buffer layers to the top surface of the set of buffer layers.

8. A photodetector device, comprising:
a substrate comprising indium arsenide (InAs);
a set of buffer layers on the substrate, the set of buffer layers providing a graded lattice constant that decreases from a bottom surface of the set of buffer layers on the substrate to a top surface of the buffer layers opposite the substrate; and
an absorber layer on the top surface of the set of buffer layers, the absorber layer comprising indium arsenide phosphide (InAsₓP₁₋ₓ) and having a lattice constant that is at least 0.4% smaller than the substrate, the lattice constant of the absorber layer being matched to the top buffer layer.

9. The photodetector of claim 8, wherein each of the set of buffer layers comprises indium arsenide phosphide (InAsₓP₁₋ₓ).

10. The photodetector of claim 8, wherein each of the set of buffer layers comprises indium aluminum arsenide (InₓAl₁₋ₓAs).

11. The photodetector of claim 8, wherein a cutoff wavelength of the photodetector is at least 1.7 micrometers.

12. The photodetector of claim 8, wherein each buffer layer of the set of buffer layers has a thickness such that a product of the thickness and a square of a residual strain of the buffer layer relative to a layer on which the buffer layer is provided is less than a predetermined value.

13. The photodetector of claim 8, wherein the set of buffer layers provide a continuously graded lattice constant from the bottom surface of the set of buffer layers to the top surface of the set of buffer layers.

14. The photodetector of claim 8, wherein the set of buffer layers provide a step-graded lattice constant from the bottom surface of the set of buffer layers to the top surface of the set of buffer layers.

15. A photodetector device, comprising:
a substrate comprising indium arsenide (InAs);
a set of buffer layers on the substrate, the set of buffer layers providing a graded lattice constant that decreases from a bottom surface of the set of buffer layers on the substrate to a top surface of the buffer layers opposite the substrate; and
an absorber layer on the top surface of the set of buffer layers, the absorber layer comprising indium aluminum arsenide (InₓAl₁₋ₓAs) and having a lattice constant that is at least 0.4% smaller than the substrate, the lattice constant of the absorber layer being matched to the top buffer layer.

16. The photodetector of claim 15, wherein each of the set of buffer layers comprises indium arsenide phosphide (InAsₓP₁₋ₓ).

17. The photodetector of claim 15, wherein each of the set of buffer layers comprises indium aluminum arsenide (InₓAl₁₋ₓAs).

18. The photodetector of claim 15, wherein a cutoff wavelength of the photodetector is at least 1.7 micrometers.

19. The photodetector of claim 15, wherein each buffer layer of the set of buffer layers has a thickness such that a product of the thickness and a square of a residual strain of the buffer layer relative to a layer on which the buffer layer is provided is less than a predetermined value.

20. The photodetector of claim 15, wherein the set of buffer layers provide a continuously graded lattice constant from the bottom surface of the set of buffer layers to the top surface of the set of buffer layers.
